(19) United States
(12) Patent Application Publication
(10) Pub. No.: US 2010/0261314 A1
(43) Pub. Date: Oct. 14, 2010

(54) THERMOSETTING DIE BONDING FILM

(76) Inventors: Naohide Takamoto, Osaka (JP); Yuuichirou Shishido, Osaka (JP)

Correspondence Address: KNOBBE MARTENS OLSON & BEAR LLP, 2040 MAIN STREET, FOURTEENTH FLOOR, IRVINE, CA, 92614, US

(21) Appl. No.: 12/755,810

(22) Filed: Apr. 7, 2010

(30) Foreign Application Priority Data
Apr. 8, 2009 (JP) 2009-094150

(51) Int. Cl. H01L 21/77; H01L 21/60; B32B 15/098

(52) U.S. Cl. 438/114; 438/118; 428/355 AK; 257/E21.509; 257/E21.598

(57) ABSTRACT

The present invention has been made and an object thereof is to provide a thermosetting die-bonding film which can remarkably reduce working hours at the time of die bonding of a semiconductor chip, and a dicing die-bonding film including the thermosetting die-bonding film and a dicing film layered to each other. The present invention relates to a thermosetting die-bonding film used to produce a semiconductor device, comprising a thermosetting catalyst in a non-crystalline state in an amount within a range from 0.2 to 1 part by weight based on 100 parts by weight of an organic component in the film.

### BACKGROUND OF THE INVENTION

1. Field of the Invention

The present invention relates to a thermosetting die-bonding film used when a semiconductor element such as a semiconductor chip is adhered and fixed on an adherend such as a substrate or a lead frame. The present invention also relates to a dicing die-bonding film including the thermosetting die-bonding film and a dicing film layered to each other.

2. Description of the Related Art

Conventionally, silver paste has been used to bond a semiconductor chip to a lead frame or an electrode member in the step of producing a semiconductor device. The treatment for the sticking is conducted by coating a paste-form adhesive on a die pad of a lead frame, or the like, mounting a semiconductor chip on the die pad, and then setting the paste-form adhesive layer.

However, about the paste-form adhesive, the amount of the coated adhesive, the shape of the coated adhesive, and on the like are largely varied in accordance with the viscosity behavior thereof, a deterioration thereof, and on the like. As a result, the thickness of the formed paste-form adhesive layer becomes uneven so that the reliability in strength of bonding a semiconductor chip is poor. In other words, if the amount of the paste-form adhesive coated on an electrode member is insufficient, the bonding strength between the electrode member and a semiconductor chip becomes low so that in a subsequent wire bonding step, the semiconductor chip is peeled. On the other hand, if the amount of the coated paste-form adhesive is too large, this adhesive flows out to stretch over the semiconductor chip so that the characteristic becomes poor. Thus, the yield or the reliability lowers. Such problems about the adhesion treatment become particularly remarkable with an increase in the size of semiconductor chips. It is therefore necessary to control the amount of the coated paste-form adhesive frequently. Thus, the workability or the productivity is deteriorated.

In this coating step of a paste-form adhesive, there is a method of coating the adhesive onto a lead frame or a forming chip by an independent operation. In this method, however, it is difficult to make the paste-form adhesive layer even. Moreover, an especial machine or a long time is required to coat the paste-form adhesive. Thus, a dicing die-bonding film which makes a semiconductor wafer to be bonded and held in a dicing step and further gives an adhesive layer, for bonding a chip, which is necessary for a mounting step is disclosed (see, for example, JP-A-60-57342).

This dicing die-bonding film has a structure wherein an adhesive layer and an adhesive layer are successively laminated on a supporting substrate. That is, a semiconductor wafer is diced in the state that the wafer is held on the adhesive layer, and then the supporting substrate is extended; the chipped works are peeled together with the adhesive layer; the peeled works are individually collected; and further the chipped works are bonded onto an adherend such as a lead frame through the adhesive layer.

JP-A-2000-104040 discloses an adhesive for thermosetting die bonding, containing a thermoplastic polyimide resin having a glass transition temperature of 90° C. or lower and a thermosetting resin. This prior art document also describes that an epoxy resin is used as the thermosetting resin and also a curing agent and a curing accelerator (a thermosetting catalyst) are used in combination.

However, such a conventional thermosetting catalyst requires a long time when the thermosetting catalyst is dissolved in an adhesive composition or a die-bonding film is thermally set.

Therefore, there is a problem that working hours become longer when a semiconductor chip is die-bonded and thermally set.

### SUMMARY OF THE INVENTION

In light of the above problem, the present invention has been made and an object thereof is to provide a thermosetting die-bonding film which can remarkably reduce working hours at the time of die bonding of a semiconductor chip, and a dicing die-bonding film including the thermosetting die-bonding film and a dicing film layered to each other.

The present inventors have intensively studied about a thermosetting die-bonding film, and a dicing die-bonding film including the thermosetting die-bonding film and a dicing film layered to each other so as to solve the above conventional problems. As a result, they have found that thermal setting can be conducted at a lower heating temperature than the conventional heat temperature within a short time by allowing a thermosetting catalyst to exist in a non-crystalline state in the thermosetting die-bonding film. Thus, the present invention has been completed.

That is, in order to solve the above-mentioned problems, the present invention relates to a thermosetting die-bonding film used to produce a semiconductor device, comprising a thermosetting catalyst in a non-crystalline state in an amount within a range from 0.2 to 1 part by weight based on 100 parts by weight of an organic component in the film.

With the constitution, by allowing a thermosetting die-bonding film (hereinafter also referred to as “die-bonding film”) to contain 0.2 parts by weight or more of a thermosetting catalyst in a non-crystalline state, it is possible to make the heating temperature lower than the conventional heating temperature when the die-bonding film is thermally set by heating and to decrease the heating time. As described above, since sufficient shearing adhesive strength can be exhibited even when the heating temperature and the heating time are decreased at the time of thermal setting, the yield can be reduced even when a semiconductor element die-bonded on an adherend is wire-bonded. It is also possible to improve long-term storage stability at room temperature by allowing the thermosetting die-bonding film to contain 1 part by weight or less of a thermosetting catalyst in a non-crystalline state. As a result, even when a semiconductor wafer is mounted to the die-bonding film of the present invention, it becomes possible to prevent the occurrence of cracks in the die-bonding film. The “non-crystalline state” in the present invention means that a film contains a thermosetting catalyst in a state where no crystallization occurs, more specifically means that a crystallization peak temperature does not exist in a differential scanning calorimetry (DSC) curve obtained under the conditions defined in JIS K 7121 using a differential scanning calorimeter.

According to the above-mentioned description, it is preferable that the thermosetting die-bonding film has a tensile fracture elongation at break of 200% or more after storage at room temperature for 30 days or more in at least one direction of a longitudinal direction and a width direction. By adjusting the tensile fracture elongation at break to 200% or more under the predetermined conditions, the occurrence of cracks in the die-bonding film can be further prevented even when a semiconductor wafer is mounted after storage at room temperature for predetermined hours. The “tensile fracture elongation at break” in the present invention is an indicator of elastic deformation tolerance and is a value of elongation at break measured at an environmental temperature of 25° C. at a tension rate of 10 mm/min in accordance with JIS-K7113. The “longitudinal direction” in the present invention means an MD (machine direction) of the film, while the “width direction” means a TD (transverse direction) intersecting perpendicularly to the longitudinal direction.

According to the above-mentioned description, it is preferable that the film contains a phenol resin, and the thermosetting catalyst has an imidazole skeleton and also exhibits solubility in the phenol resin.

According to the above-mentioned description, it is preferable that the thermosetting catalyst is a salt having a triphenylphosphine structure, a salt having a triphenylborane structure, or has an amino group. These thermosetting catalysts enable initiation of thermal setting of the die-bonding film by conducting a heating treatment.

According to the above-mentioned description, it is preferable that the thermosetting catalyst is a photo-acid-generating agent. By irradiating the die-bonding film with visible rays or ultraviolet rays, the photo-acid-generating agent is photolyzed to generate an acid, thus making it possible to initiate thermal setting of the film.

According to the above-mentioned description, it is preferable that the thermosetting die-bonding film has a tensile storage modulus of 10 MPa or more after thermal setting at 260° C. By adjusting the tensile storage modulus at 260° C. to 10 MPa or more after thermal setting, for example, it is possible to prevent the occurrence of shear deformation on the adhering surface between the die-bonding film and an adherend such as a lead frame due to ultrasonic vibration or heating even when wire bonding is conducted to a semiconductor element such as a semiconductor chip adhered on a thermosetting die-bonding film. As a result, it is possible to enhance success probability of wire bonding and to further improve the yield of the production of a semiconductor device.

According to the above-mentioned description, it is preferable that the thermosetting die-bonding film according to claim 1, which has a surface energy of 40 mJ/m² or less on the laminating surface after thermal setting. By adjusting the surface energy on the laminating surface of the thermosetting die-bonding film to 40 mJ/m² or less as above constitution, the wettability and adhesive strength in the laminating surface can be improved. As a result, it becomes possible to suppress the generation of bubbles (voids) at the boundary between the die-bonding film and the adherend even when the semiconductor element is die-bonded with the adherend, and therefore, favorable tackiness can be exhibited.

According to the above-mentioned description, it is preferable that the thermosetting die-bonding film has a moisture absorptivity of 1% by weight or less when the thermosetting die-bonding film is allowed to stand under the atmosphere of 85° C. and 85% RH for 168 hours after thermal setting. By adjusting the moisture absorptivity to 1% by weight or less, for example, the occurrence of voids in the reflow step can be prevented.

According to the above-mentioned description, it is preferable that the thermosetting die-bonding film has a weight loss of 1% by weight or less after heating at 250° C. for 1 hour after thermal setting. By adjusting the weight loss to 1% by weight or less, the occurrence of cracks in a package during the reflow step can be prevented.

That is, in order to solve the above-mentioned problems, the present invention relates to a dicing die-bonding film comprising dicing film and the thermosetting die-bonding film layered on the dicing film, wherein the dicing film has a structure including a base material and a pressure-sensitive adhesive layer layered on the base material, and the thermosetting die-bonding film is layered on the adhesive layer.

That is, in order to solve the above-mentioned problems, the present invention relates to a method for producing a semiconductor device using the dicing die-bonding film comprising: a mounting step of laminating the dicing die-bonding film on a back surface of a semiconductor wafer using the thermosetting die-bonding film as a laminating surface; a dicing step of dicing the semiconductor wafer together with the thermosetting die-bonding film to form a chip-shaped semiconductor element; a pickup step of picking up the semiconductor element from the dicing die-bonding film together with the thermosetting die-bonding film; a die-bonding step of die-bonding the semiconductor element on an adherend through the thermosetting die-bonding film; a thermal setting step of thermally setting the thermosetting die-bonding film by heating at a heating temperature within a range from 80 to 200° C. and a heating time within a range from 0.1 to 24 hours; and a wire bonding step of wire bonding to the semiconductor element.

In the present invention, as the die-bonding film for die bonding of the semiconductor element on the adherend, a film containing a thermosetting catalyst in a non-crystalline is used. Since the die-bonding film is also excellent in long-term storage stability at room temperature, for example, cracks do not arise in the die-bonding film even when a semiconductor wafer is laminated to the die-bonding film and then stored at room temperature for a long period. The die-bonding film exhibits sufficient shearing adhesive strength even when the heating temperature and the heating time are decreased at the time of thermal setting. Therefore, in the thermal setting step after the die-bonding step, a decrease in the heating temperature (within a range from 80 to 200° C.) and a decrease in the heating time (within a range from 0.1 to 24 hours) can be achieved. That is, the method for producing a semiconductor device of the present invention can improve working efficiency as compared with a conventional method for producing a semiconductor device, thus making it possible to decrease the yield.

### BRIEF DESCRIPTION OF THE DRAWINGS

FIG. 1 is a schematic sectional view showing a dicing-die-bonding film according to one embodiment of the present invention;

FIG. 2 is a schematic sectional view showing another dicing die-bonding film according to the embodiment;

FIG. 3 is a schematic sectional view showing en example in which a semiconductor chip is mounted through a die-bonding film in the dicing die-bonding film;

FIG. 4 is a schematic sectional view showing en example in which a semiconductor chip is three-dimensionally mounted through a die-bonding film in the dicing die-bonding film;

FIG. 5 is a schematic sectional view showing an example in which two semiconductor chip are three-dimensionally mounted by a die-bonding film through a spacer using the dicing die-bonding film; and

FIG. 6 is a schematic sectional view showing an example in which two semiconductor chips are three-dimensionally mounted through a die-bonding film without using the spacer.

### DESCRIPTION OF THE EMBODIMENTS

Dicing Die-Bonding Film

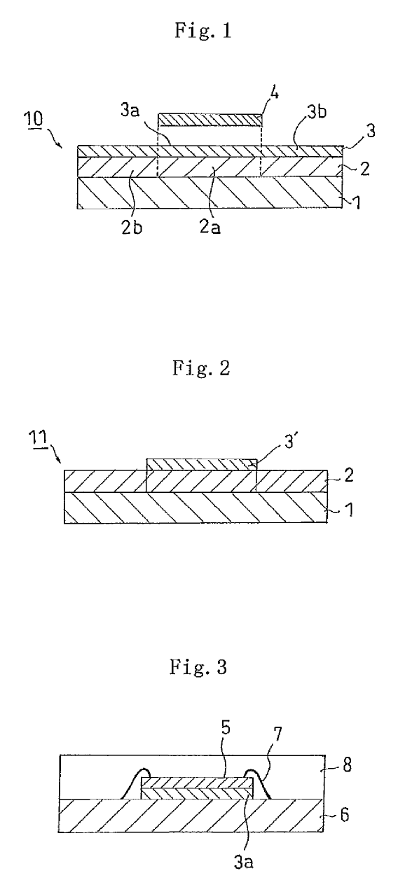

The thermosetting die-bonding film (hereinafter referred to as “die-bonding film”) of the present invention will be described below by way of a dicing die-bonding film layered integrally with a dicing film as an example. FIG. 1 is a schematic sectional view showing a dicing die-bonding film according to the present embodiment. FIG. 2 is a schematic sectional view showing another dicing die-bonding film according to the present embodiment.

As shown in FIG. 1, a dicing die-bonding film 10 has a constitution in which a die-bonding film 3 is layered on a dicing film 11. The dicing film 11 is constituted by layering a pressure-sensitive adhesive layer 2 on a base material 1, and the die-bonding film 3 is provided on the adhesive layer 2. As shown in FIG. 2, the present invention may have a constitution such that a die-bonding film 3′ is formed only at the portion to which workpieces are laminated.

The base material 1 has ultraviolet transparency and is a strength matrix of the dicing die-bonding films 10, 11. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene(meth)acrylic acid copolymer; an ethylene(meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper.

Further, the material of the base material 1 includes a polymer such as a cross-linked body of the above resins. The above plastic film may be also used unstretched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 2 and the die-bonding films 3, 3′ is reduced by thermally shrinking the base material 1 after dicing, and the recovery of the semiconductor chips (a semiconductor element) can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base material 1 in order to improve adhesiveness, holding properties, etc. with the adjacent layer. The same type or different type of base material can be appropriately selected and used as the base material 1, and a base material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the base material 1 in order to give an antistatic function to the base material 1. The base material 1 may be a single layer or a multi layer of two or more types.

The thickness of the base material 1 can be appropriately decided without limitation particularly. However, it is generally about 5 to 200 v.

The pressure-sensitive adhesive layer 2 is constituted by containing a ultraviolet curable pressure sensitive adhesive. The ultraviolet curable pressure sensitive adhesive can easily decrease its adhesive strength by increasing the degree of crosslinking by irradiation with ultraviolet. By radiating only a part 2a corresponding to the semiconductor wafer pasting part of the pressure-sensitive adhesive layer 2 shown in FIG. 2, a difference of the adhesive strength to another part 2b can be also provided.

Further, by curing the ultraviolet curable pressure-sensitive adhesive layer 2 with the die-bonding film 3′ shown in FIG. 2, the part 2a in which the adhesive strength is remarkably decreased can be formed easily. Because the die-bonding film 3′ is pasted to the part 2a in which the adhesive strength is decreased by curing, the interface of the part 2a of the pressure-sensitive adhesive layer 2 and the die-bonding film 3′ has a characteristic of being easily peeled during pickup. On the other hand, the part not radiated by ultraviolet rays has sufficient adhesive strength, and forms the part 2b.

As described above, in the pressure-sensitive adhesive layer 2 of the dicing die-bonding film 10 shown in FIG. 1, the part 2b formed by a non-cured ultraviolet curable pressure sensitive adhesive sticks to the die-bonding film 3, and the holding force when dicing can be secured. In such a way, the ultraviolet curable pressure sensitive adhesive can support the die-bonding film 3 for fixing the semiconductor chip onto an adherend such as a substrate with good balance of adhesion and peeling. In the pressure-sensitive adhesive layer 2 of the dicing die-bonding film 11 shown in FIG. 2, a dicing ring can be fixed to the part 2b.

The ultraviolet curable pressure sensitive adhesive that is used has a ultraviolet curable functional group of a radical reactive carbon-carbon double bond, etc., and adherability. Examples of the ultraviolet curable pressure sensitive adhesive are an added type ultraviolet curable pressure sensitive adhesive in which a ultraviolet curable monomer component or an oligomer component is compounded into an acryl pressure sensitive adhesive or a rubber pressure sensitive adhesive.

The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Specific examples of the acryl polymers include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl(meth)acrylate, carboxypentyl(meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxylmethylcyclohexyl)methyl(meth)acrylate; sulfonic acid group containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer(s) to be used is preferably 40% or less by weight of all the monomer components.

For crosslinking, the acrylic polymer can also contain multifunctional monomers if necessary as the copolymerizable monomer component. Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy(meth)acrylate, polyester(meth)acrylate, urethane(meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the above acryl polymer can be performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight average molecular weight of 300000 or more, particularly 400000 to 30000000 is as a main component are preferable from such viewpoint, the pressure-sensitive adhesive can be made to be an appropriate cross-linking type with an internal cross-linking manner, an external cross-linking manner, etc.

To increase the number-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. Generally, the crosslinking agent is preferably incorporated in an amount of about 5 parts by weight or less based on 100 parts by weight of the base polymer. The lower limit of the crosslinking agent is preferably 0.1 parts by weight or more. The pressure-sensitive adhesive may be blended not only with the components described above but also with a wide variety of conventionally known additives such as a tackifier, and aging inhibitor, if necessary.

Examples of the ultraviolet curable monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the ultraviolet curable oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the ultraviolet ray curable monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 40 to 150 parts by weight based on 100 parts by weight of the base polymer such as an acryl polymer constituting the pressure sensitive adhesive.

Further, besides the added type ultraviolet curable pressure sensitive adhesive described above, the ultraviolet curable pressure sensitive adhesive includes an internal ultraviolet curable pressure sensitive adhesive using an acryl polymer having a radical reactive carbon-carbon double bond in the polymer side chain, in the main chain, or at the end of the main chain as the base polymer. The internal ultraviolet curable pressure sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive over time.

The above-mentioned base polymer, which has a carbon-carbon double bond, maybe any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into aside chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radial ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups maybe present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, isocyanate, and m-isopropenyl-α,α-dimethylbenzyl isocyanate. The used acrylic polymer may be an acrylic polymer copolymerized with any one of the hydroxyl-containing monomers exemplified above, or an ether compound such as 2-hydroxyethyl vinyl ether, 4-hydroxybutyl vinyl ether or diethylene glycol monovinyl ether.

The intrinsic type radial ray curable adhesive may be made only of the above-mentioned base polymer (in particular, the acrylic polymer), which has a carbon-carbon double bond. However, the above-mentioned radial ray curable monomer component or oligomer component may be incorporated into the base polymer to such an extent that properties of the adhesive are not deteriorated. The amount of the radial ray curable oligomer component or the like is usually 30 parts or less by weight, preferably from 0 to 10 parts by weight for 100 parts by weight of the base polymer.

In the case that the radial ray curable adhesive is cured with ultraviolet rays or the like, a photopolymerization initiator is incorporated into the adhesive. Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

Further, examples of the ultraviolet curing type pressure-sensitive adhesive which is used in the formation of the pressure-sensitive adhesive layer 2 include such as a rubber pressure-sensitive adhesive or an acryl pressure-sensitive adhesive which contains an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine, and an onium salt compound, which are disclosed in JP-A No. 60-196956. Examples of the above addition-polymerizable compound having two or more unsaturated bonds include such as polyvalent alcohol ester or oligoester of acryl acid or methacrylic acid and an epoxy or a urethane compound.

The method of forming the part 2a in the pressure-sensitive adhesive layer 2 includes a method of forming the ultraviolet curable pressure-sensitive adhesive layer 2 on the base material 1 and then radiating the part 2a with ultraviolet partially and curing. The partial ultraviolet irradiation can be performed through a photo mask in which a pattern is formed which is corresponding to a part 3b, etc. other than the semiconductor wafer pasting part 3a. Further, examples include a method of radiating in a spot manner and curing, etc. The formation of the ultraviolet curable pressure-sensitive adhesive layer 2 can be performed by transferring the pressure-sensitive adhesive layer provided on a separator onto the base material 1. The partial ultraviolet curing can be also performed on the ultraviolet curable pressure-sensitive adhesive layer 2 provided on the separator.

In the pressure-sensitive adhesive layer 2 of the dicing die-bonding film 10, the ultraviolet irradiation may be performed on a part of the pressure-sensitive adhesive layer 2 so that the adhesive strength of the part 2a becomes smaller than the adhesive strength of other parts 2b. That is, the part 2a in which the adhesive strength is decreased can be formed by using those in which the entire or a portion of the part other than the part corresponding to the semiconductor wafer pasting part 3a on at least one face of the base material 1 is shaded, forming the ultraviolet curable pressure-sensitive adhesive layer 2 onto this, then radiating ultraviolet, and curing the part corresponding the semiconductor wafer pasting part 3a. The shading material that can be a photo mask on a supporting film can be manufactured by printing, vapor deposition, etc. Accordingly, the dicing die-bonding film 10 of the present invention can be produced with efficiency.

The thickness of the pressure-sensitive adhesive layer 2 is not particularly limited. However, it is preferably about 1 to 50 μm from the viewpoint of preventing chipping of the chip cut surface, compatibility of fixing and holding of the adhesive layer, and the like. It is preferably 2 to 30 μm, and further preferably 5 to 25 μm.

The die-bonding films 3, 3′ contain a thermosetting catalyst in a non-crystalline state. It is preferred that the thermosetting catalyst is uniformly mixed in the die-bonding films 3, 3′ and dispersed without being crystallized. Herein, the content of the thermosetting catalyst is preferably from 0.2 to 1 part by weight, and more preferably 0.3 to 0.6 parts by weight, based on 100 parts by weight of the organic component in the film. When the content of the thermosetting catalyst is 1 part by weight or less, long-term storage stability at room temperature can be improved. As a result, even when a semiconductor wafer or the like is mounted to the die-bonding film of the present invention, the occurrence of cracks in the die-bonding film can be prevented. On the other hand, when the content is 0.2 parts by weight or more, at the time of thermal setting of the die-bonding films 3, 3′ by heating, the heating temperature can be decreased as compared with the conventional heating temperature, and also the heating time can be decreased.

The thermosetting catalyst is not particularly limited and includes, for example, a salt having an imidazole skeleton, a salt having a triphenylphosphine structure, a salt having a triphenylborane structure, and those having an amine group.

The salt having an imidazole skeleton preferably has solubility in a phenol resin (details will be described hereinafter), which is a constituent material of the die-bonding films 3, 3′. However, the thermosetting catalyst composed of the salt having an imidazole skeleton is preferably contained in the die-bonding films 3, 3′ in a non-crystalline state. Therefore, for example, the salt having an imidazole skeleton may be insoluble in a solution of an adhesive composition described hereinafter. Specific examples thereof include 2-phenylimidazole (trade name; 2PZ), 2-ethyl-4-methylimidazole (trade name; 2E4MZ), 2-methylimidazole(trade name; 2MZ), 2-undecylimidazole (trade name; C11Z), 2-phenyl-4,5-dihydroxymethylimidazole (trade name; 2-PHZ) and 2,4-diamino-6-(2′-methylimidazolyl (1)′)ethyl-s-triazinisocyanuric acid adduct (trade name; 2MAOK-PW) (all of which are manufactured by SHIKOKU CHEMICALS CORPORATION). The “solubility” means a property in which the thermosetting catalyst composed of the salt having an imidazole skeleton dissolves in a solvent containing a phenol resin, and more specifically means that at least 10% by weight or more of the thermosetting catalyst dissolves at the temperature within a range from 10 to 40° C.

The salt having a triphenylphosphine structure is not particularly limited and includes, for example, triorganophosphines such as triphenylphosphine, tributylphosphine, tri(p-methylphenyl)phosphine, tri(nonylphenyl)phosphine and diphenyltolylphosphine, tetraphenylphosphonium bromide (TPP-PB), methyltriphenylphosphonium (trade name; TPP-MB), methyltriphenylphosphonium chloride (trade name; TPP-MC), methoxymethyltriphenylphosphonium (trade name; TPP-MOC) and benzyltriphenylphosphonium chloride (trade name; TPP-ZC) (all of which are manufactured by HOKKO CHEMICAL INDUSTRY CO., LTD.). When the die-bonding films 3, 3′ contain an epoxy resin to be constituted, the thermosetting catalyst preferably has a triphenylphosphine structure and also substantially exhibits insolubility in the epoxy resin. When the thermosetting catalyst is insoluble in the epoxy resin, it is possible to suppress thermal setting from excessively proceeding. The thermosetting catalyst which has a triphenylphosphine structure and also substantially exhibits insolubility in the epoxy resin includes, for example, methyltriphenylphosphonium (trade name; TPP-MB). The “insolubility” means that the thermosetting catalyst composed of the salt having a triphenylphosphine structure is insoluble in a solvent composed of an epoxy resin, and more specifically means that 10% by weight or more of the thermosetting catalyst does not dissolve at the temperature within a range from 10 to 40° C.

The salt having a triphenylborane structure is not particularly limited and further includes, for example, tri(p-methylphenyl)phosphine. The salt having a triphenylborane structure includes those having also a triphenylphosphine structure. The salt having a triphenylphosphine structure and a triphenylborane structure is not particularly limited and includes tetraphenylphosphonium tetraphenylborate (trade name; TPP-K), tetraphenylphosphonium tetra-p-triborate (trade name; TPP-MK), benzyltriphenylphosphonium tetraphenylborate (trade name; TPP-ZK) and triphenylphosphine triphenylborane (trade name; TPP-S) (all of which are manufactured by HOKKO CHEMICAL INDUSTRY CO., LTD.).

The thermosetting catalyst having an amino group is not particularly limited and includes, for example, monoethanolamine trifluoroborate (manufactured by Stella Chemifa Corporation) and dicyandiamide (manufactured by NACALAI TESQUE, INC.).

The thermosetting catalyst according to the present invention may be a photo-acid-generating agent, in addition to those described above. When the die-bonding film is irradiated with visible rays or ultraviolet rays, the photo-acid-generating agent is photolyzed to generate an acid, thus making it possible to initiate thermal setting of the film. The photo-acid-generating agent is not particularly limited and includes, for example, bis(cyclohexylsulfonyl)diazomethane (manufactured by Wako Pure Chemical Industries, WPAG-145).

Various thermosetting catalysts described above can be used alone, or two or more kinds of them can be used in combination. The shape of the thermosetting catalyst is not particularly limited and those having a spherical or ellipsoidal shape can be used.

Regarding the die-bonding films 3, 3′, the tensile storage modulus after thermal setting by heating at 260° C. is preferably 10 MPa or more, and more preferably within a range from 10 to 50 MPa. Therefore, during the wire bonding step, shear deformation does not arise on the adhering surface between the die-bonding films 3, 3′ and the adherend due to ultrasonic vibration and heating. Thus, success probability of wire bonding can be improved. The heating conditions when the die-bonding films 3, 3′ are thermally set will be described in detail hereinafter.

In the die-bonding films 3, 3′, the surface energy on the laminating surface after thermal setting is preferably 40 mJ/m² or less. When the surface energy is 40 mJ/m² or less, the wettability and adhesive strength on the laminating surface can be improved, and thus even when a semiconductor element is die-bonded with an adherend, it becomes possible to suppress the generation of bubbles (voids) at the boundary between the die-bonding film and the adherend, and to exhibit satisfactory tackiness. The lower limit of the surface energy is preferably 37 mJ/m² or more, thus making it possible to improve adhesion to the adherend such as a substrate.

The moisture absorptivity of the die-bonding films 3, 3′ after thermal setting is preferably 1% by weight or less, and more preferably 0.8% by weight or less. The occurrence of voids in the reflow step can be prevented by adjusting the moisture absorptivity to 1% by weight or less. The moisture absorptivity can be adjusted by changing the addition amount of an inorganic filler. The moisture absorptivity is calculated from the weight change when the die-bonding film is allowed to stand under the atmosphere of 85° C. and 85% RH for 168 hours.

Furthermore, the weight loss of the die-bonding films 3, 3′ after thermal setting is preferably 1% by weight or less, and more preferably 0.8% by weight or less. The generation of cracks in a package during the reflow step can be prevented by adjusting the weight loss to 1% by weight or less. The weight loss can be adjusted, for example, by the addition of an inorganic substance which can reduce the generation of cracks at the time of lead-free solder flow. The weight loss is calculated from the weight change when the die-bonding film is heated under the conditions of 260° C. for 1 hour.

The die-bonding film according to the present embodiment made only of a single adhesive layer, and a multi-layered adhesive sheet wherein an adhesive layer or adhesive layers is/are formed on a single face or both faces of a core member. Examples of the core member include films (such as polyimide film, polyester film, polyethylene terephthalate film, polyethylene naphthalate film, and polycarbonate film); resin substrates which are reinforced with glass fiber or plastic nonwoven finer; silicon substrates; and glass substrates.

The adhesive composition constituting the die-bonding films 3, 3′ include those in which a thermoplastic resin is used in combination with a thermosetting resin. Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl and (4-hydroxymethylcyclohexyl)methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl(meth)acrylate, and (meth)acryloyloxynaphthalenesulfonic acid; and monomers which contain a phosphoric acid group, such as 2-hydroxyethylacryloyl phosphate.

The blending ratio of the thermosetting resin is not particularly limited as long as the die-bonding films 3, 3′ can function as thermosetting die-bonding films when heated under predetermined conditions, and is preferably within a range from 5 to 60% by weight, and more preferably within a range from 10 to 50% by weight.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

In the present invention, die-bonding film comprising the epoxy resin, the phenol resin, and an acrylic resin is particularly preferable. Since these resins contain ionic impurities in only a small amount and have high heat resistance, the reliability of the semiconductor element can be ensured. About the blend ratio in this case, the amount of the mixture of the epoxy resin and the phenol resin is from 10 to 200 parts by weight for 100 parts by weight of the acrylic resin component.

In order to crosslink the die-bonding film 3, 3′ of the present invention to some extent in advance, it is preferable to add, as a crosslinking agent, a polyfunctional compound which reacts with functional groups of molecular chain terminals of the above-mentioned polymer to the materials used when the sheet 12 is produced. In this way, the adhesive property of the sheet at high temperatures is improved so as to improve the heat resistance.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

An inorganic filler may be appropriately incorporated into the die-bonding film 3, 3′ of the present invention in accordance with the use purpose thereof. The incorporation of the inorganic filler makes it possible to confer electric conductance to the sheet, improve the thermal conductivity thereof, and adjust the elasticity. Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used. The average particle size of the inorganic filler is preferably from 0.1 to 80 μm. The blending ratio of the inorganic filler is preferably set within a range from 0 to 80 parts by weight, and particularly preferably from 0 to 70 parts by weight, based on 100 parts by weight of the organic resin component.

If necessary, other additives besides the inorganic filler may be incorporated into the die-bonding film 3, 3′ of the present invention. Examples thereof include a flame retardant, a silane coupling agent, and an ion trapping agent. Examples of the flame retardant include antimony trioxide, antimony pentaoxide, and brominated epoxy resin. These may be used alone or in combination of two or more thereof. Examples of the silane agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These may be used alone or in combination of two or more thereof.

The thickness of the die-bonding film 3, 3′ (in the case that the film is a laminate, the total thickness thereof) is not particularly limited, and is, for example, from about 5 to 100 μm, preferably from about 5 to 50 μm.

The die-bonding films 3, 3′ of the dicing die-bonding films 10, 11 are preferably protected by a separator (not shown). The separator has a function as a protecting material that protects the die-bonding films 3, 3′ until they are practically used. Further, the separator can be used as a supporting base material when transferring the die-bonding films 3, 3′ to the pressure-sensitive adhesive layer 2. The separator is peeled when pasting a workpiece onto the die-bonding films 3, 3′ of the dicing die-bonding film. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator.

The dicing die-bonding films 10, 11 according to the present embodiment are produced, for example, by the following procedure.

First, the base material 1 can be formed by a conventionally known film-forming method. The film-forming method includes, for example, a calendar film-forming method, a casting method in an organic solvent, an inflation extrusion method in a closed system, a T-die extrusion method, a co-extrusion method, and a dry lamination method.

Next, a pressure-sensitive adhesive composition solution is applied on the base material 1 to form a coated film and the coated film is dried under predetermined conditions (optionally crosslinked with heating) to form the pressure-sensitive adhesive layer 2. Examples of the application method include, but are not limited to, roll coating, screen coating and gravure coating methods. Drying is conducted under the drying conditions, for example, the drying temperature within a range from 80 to 150° C. and the drying time within a range from 0.5 to 5 minutes. The pressure-sensitive adhesive layer 2 may also be formed by applying a pressure-sensitive adhesive composition on a separator to form a coated film and drying the coated film under the drying conditions. Then, the pressure-sensitive adhesive layer 2 is laminated on the base material 1 together with the separator. Thus, the dicing film 11 is produced.

The die-bonding films 3, 3′are produced, for example, by the following procedure.

First, an adhesive composition solution as a material for forming the dicing die-bonding films 3, 3′ is produced. As described above, the adhesive composition solution is blended with the adhesive composition, a thermosetting catalyst, and various additives. At this time, it is preferred that the thermosetting catalyst in the adhesive composition solution is uniformly dissolved without being crystallized. The thermosetting catalyst according to the present invention enables reduction in the time required to dissolve in the adhesive composition solution. Specifically, when within a range from 0.2 to 1 part by weight of the thermosetting catalyst is dissolved in 100 parts by weight of the organic component, the dissolution time is within a range from 0.1 to 2 hours. However, unless the thermosetting catalyst is not crystallized in the thus formed film, it may be crystallized in the adhesive composition solution, or may be an insoluble state without being dispersed.

Next, the adhesive composition solution is applied on a substrate separator to form a coated film having a predetermined thickness and the coated film is dried under predetermined conditions to form an adhesive layer. Examples of the application method include, but are not limited to, roll coating, screen coating and gravure coating methods. Drying is conducted under the drying conditions, for example, the drying temperature within a range from 70 to 160° C. and the drying time within a range from 1 to 5 minutes. An adhesive layer may also be formed by applying a pressure-sensitive adhesive composition solution on a separator to form a coated film and drying the coated film under the drying conditions. On the substrate separator, the adhesive layer is layered together with a separator.

Subsequently, each separator is peeled from the dicing film 11 and the adhesive layer and both are laminated to each other so that the adhesive layer and the pressure-sensitive adhesive layer serve as a laminating surface. Lamination is conducted, for example, by contact bonding. At this time, the lamination temperature is not particularly limited and is, for example, preferably from 30 to 50° C., and more preferably from 35 to 45° C. The linear pressure is not particularly limited and is, for example, from 0.1 to 20 kgf/cm, and more preferably from 1 to 10 kgf/cm. Then, the substrate separator on the adhesive layer is peeled to obtain the dicing die-bonding film according to the present embodiment.

(Producing Method of Semiconductor Device)

The dicing die-bonding films 10, 11 of the present invention are used as follows by appropriately peeling the separator arbitrarily provided on the die-bonding films 3, 3′. Hereinbelow, referring to FIG. 3, it is described while using the dicing die-bonding 11 as an example.

First, a semiconductor wafer 4 is press-adhered on the die-bonding film 3 in the dicing die-bonding film 10, and it is fixed by adhering and holding (mounting step). The present step is performed while pressing with a pressing means such as a pressing roll. The laminating temperature at the time of mounting is not particularly limited and is, for example, preferably within a range from 20 to 80° C.

Next, the dicing of the semiconductor wafer 4 is performed. Accordingly, the semiconductor wafer 4 is cut into a prescribed size and individualized, and a semiconductor chip 5 is produced. The dicing is performed following a normal method from the circuit face side of the semiconductor wafer 4, for example. Further, the present step can adopt such as a cutting method called full-cut that forms a slit in the dicing die-bonding film 10. The dicing apparatus used in the present step is not particularly limited, and a conventionally known apparatus can be used. Further, because the semiconductor wafer 4 is adhered and fixed by the dicing die-bonding film 10, chip crack and chip fly can be suppressed, and at the same time the damage of the semiconductor wafer can be also suppressed.

Pickup of the semiconductor chip 5 is performed in order to peel a semiconductor chip 5 that is adhered and fixed to the dicing die-bonding film 10. The method of picking up is not particularly limited, and conventionally known various methods can be adopted. Examples include a method of pushing up the individual semiconductor chip 5 from the dicing die-bonding 10 side with a needle and picking up the pushed semiconductor chip 5 with a picking-up apparatus.

Here, the picking up is performed after radiating the pressure-sensitive adhesive layer 2 with ultraviolet rays because the pressure-sensitive adhesive layer 2 is an ultraviolet curable type pressure-sensitive adhesive layer. Accordingly, the adhesive strength of the pressure-sensitive adhesive layer 2 to the die-bonding film 3a decreases, and the peeling of the semiconductor chip 5 becomes easy. As a result, picking up becomes possible without damaging the semiconductor chip 5. The condition such as irradiation intensity and irradiation time when irradiating an ultraviolet ray is not particularly limited, and it may be appropriately set depending on necessity. Further, the light source as described above can be used as a light source used in the ultraviolet irradiation.

The semiconductor chip 5 picked up is adhered and fixed to an adherend 6 through the die-bonding film 3a interposed therebetween (die bonding). Examples of the adherend 6 include such as a lead frame, a TAB film, a substrate, and a semiconductor chip separately produced. The adherend 6 may be a deformable adherend that are easily deformed, or may be a non-deformable adherend (a semiconductor wafer, etc.) that is difficult to deform, for example.

A conventionally known substrate can be used as the substrate.

Further, a metal lead frame such as a Cu lead frame and a 42 Alloy lead frame and an organic substrate composed of glass epoxy, BT (bismaleimide-triazine), and polyimide can be used as the lead frame. However, the present invention is not limited to this, and includes a circuit substrate that can be used by mounting a semiconductor element and electrically connecting with the semiconductor element.

The die-bonding film 3 is a thermosetting type. Accordingly, the die-bonding film 3a is heated, thereby setting the film thermally so as to stick and fix the semiconductor chip 5 onto the adherend 6. In this way, the heat-resisting strength of the resultant is improved. The present invention can decrease the heating temperature compared with a conventional die-bonding film, and can attempt shortening the heating time. About conditions for the heating, the temperature ranges from 80 to 200° C., preferably from 100 to 175° C., more preferably from 100 to 140° C. The heating time is from 0.1 to 24 hours, preferably from 0.1 to 3 hours, more preferably from 0.2 to 1 hour. Here, those in which the semiconductor chip 5 is adhered and fixed to a substrate, etc. through the semiconductor wafer pasting part 3a interposed therebetween can be used in a reflow step.

The die-bonding film 3 after thermosetting may be a die-bonding film having a shearing adhesive strength of 0.2 MPa or more, preferably 0.2 to 10 MPa onto the adherend 6. The shearing adhesive strength of the die-bonding film 3a is at least 0.2 Mpa or more; therefore, even if a wire bonding step is performed by way of no heating step, shearing deformation is not generated in the bonding face between the die-bonding film 3a and the semiconductor chip 5 or the adherend 6 by ultrasonic vibration or heating in the wire bonding step. In other words, the semiconductor element is not moved by ultrasonic vibration in the wire bonding step, thereby preventing a fall in the success probability of the wire bonding.

According to the method for producing a semiconductor device according to the present invention, wire bonding may be conducted without passing through the thermal setting step due to a heating treatment of the die-bonding film 3, and also the semiconductor chip 5 may be sealed with a sealing resin and then the sealing resin may be post-cured. In this case, the shearing adhesive strength of the die-bonding film 3 upon temporary fixation is preferably 0.2 MPa or more, and more preferably 0.2 to 10 MPa, to the adherend 6. When the shearing adhesive strength of the die-bonding film 3 upon temporary fixation is at least 0.2 MPa or more, shear deformation does not arise on the adhering surface between the die-bonding film 3 and the semiconductor chip 5 or the adherend 6 due to ultrasonic vibration or heating in this step even when the wire bonding step is conducted without passing through the heating step. That is, the semiconductor element does not move due to ultrasonic vibration at the time of wire bonding, thus preventing the decrease in the success probability of wire bonding.

The wire bonding step is a step of connecting tips of terminal moieties (inner leads) of the adherend 6 electrically with electrode pads (not illustrated) on the semiconductor chip 5 through bonding wires 7 (see FIG. 3). The bonding wires 7 may be, for example, gold wires, aluminum wires, or copper wires. The temperature when the wire bonding is performed is from 80 to 250° C., preferably from 80 to 220° C. The heating time is from several seconds to several minutes. The connection of the wires is performed by using a combination of vibration energy based on ultrasonic waves with compression energy based on the application of pressure in the state that the wires are heated to a temperature in the above-mentioned range. The present step can be conducted without thermal setting of the die-bonding film 3a. In the process of the step, the semiconductor chip 5 and the adherend 6 are not fixed to each other by the die-bonding film 3a.

The above-mentioned sealing step is a step of sealing the semiconductor element 13 with a sealing resin 8 (see FIG. 1(c)), and is performed to protect the semiconductor element 13 and the bonding wires 16 mounted on the adhernd 6. The present step is performed by molding the sealing resin with a mold or die. The sealing resin 8 may be, for example, an epoxy resin. The heating for the resin-sealing is performed usually at 175° C. for 60 to 90 seconds. In the this invention, however, the heating is not limited to this, and may be performed, for example at 165 to 185° C. for several minutes. In such a way, the sealing resin is cured and further the semiconductor chip 5 and the adhernd 6 are set to each other through the adhesive sheet 3a. In short, even if the below mentioned post-curing step, which will be detailed later, is not performed in this invention, the sticking/fixing based on the adhesive sheet 3a can be attained in the present step so that the number of the producing steps can be reduced and the term for producing the semiconductor device can be shortened.

In the post-curing step, the sealing resin 8, which is not sufficiently cured in the sealing step, is completely cured. Even if the die-bonding film 3a is not completely cured in the step of sealing, the die-bonding film 3a and sealing resin 8 can be completely cured in the present step. The heating temperature in the present step is varied dependently on the kind of the sealing resin, and is, for example, in the range of 165 to 185° C. The heating time is from about 0.5 to 8 hours.

The dicing die-bonding film of the invention also can be preferably used in the case of three-dimensional mounting also in which plural semiconductor chips are laminated, as illustrated in FIG. 4. FIG. 4 is a schematic sectional view illustrating an example wherein semiconductor chips are three-dimensionally mounted through a die-bonding film. In the case of the three-dimensional mounting illustrated in FIG. 4, at least one die-bonding film 3a cut out so as to have a size equal to that of a semiconductor chip 5 is bonded to a adherend 6, and then the semiconductor chip 5 is bonded onto the adherend 6 through the die-bonding film 3a so as to direct its wire bonding face upwards. Next, a die-bonding film 13 is bonded onto the semiconductor chip 5 avoiding its electrode pad portions. Furthermore, another semiconductor chip 15 is bonded onto the die-bonding film 13 so as to direct its wire bonding face upwards.

Next, a wire bonding step is performed. In this way, individual electrode pads on the semiconductor chip 5 and the other semiconductor chip 15 are electrically connected with the adherend 6 through bonding wires 7. In the case of the above-mentioned temporary bonding, the present step is carried out by way of no heating step.

Subsequently, a sealing step of sealing the semiconductor chip 5 and on the like with a sealing resin 8 is performed to cure the sealing resin. In addition thereto, in the case of the temporary sticking/fixing, the adherend 6 and the semiconductor chip 5 are bonded to each other through the die-bonding film 3a. Also, the semiconductor chip 5 and the other semiconductor chip 15 are bonded to each other through the die-bonding film 13. After the sealing step, an after-curing step may be performed.

In the case of the three-dimensional mounting of the semiconductor chips, the production process is simplified and the yield is improved since heating treatment by heating the die-bonding films 3a and 13 is not conducted. Furthermore, the adherend 6 is not warped, and the semiconductor chips 5 and 15 are not cracked; thus, the semiconductor element can be made still thinner.

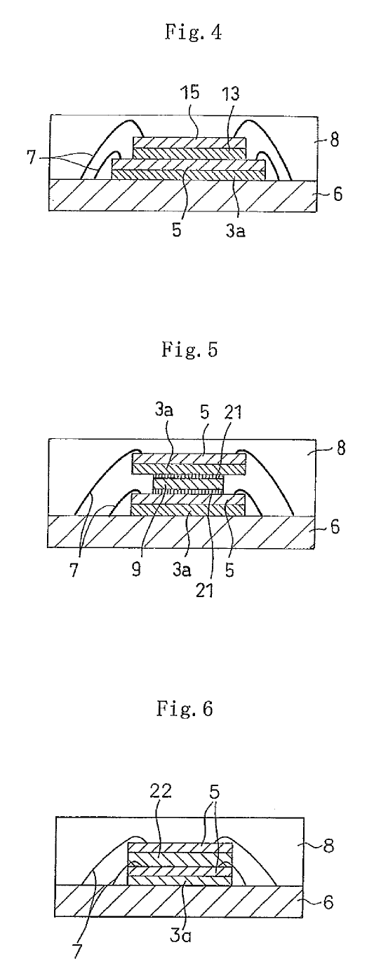

Three-dimensional mounting may performed in which semiconductor chips are laminated through die-bonding films so as to interpose a spacer between the semiconductor chips, as illustrated in FIG. 5. FIG. 5 is a schematic sectional view illustrating an example wherein two semiconductor chips are three-dimensionally mounted through die-bonding films so as to interpose a spacer between the chips.

In the case of the three-dimensional mounting illustrated in FIG. 5, first, a die-bonding film 3a, a semiconductor chip 5, and a die-bonding film 21 are successively laminated on the adherend 6 to bond these members. Furthermore, on the die-bonding film 21 are successively laminated a spacer 9, another die-bonding film 21, another die-bonding film 3a, and another semiconductor chip 5 to bond these members.

Next, as illustrated in FIG. 5, a wire bonding step is performed. In this way, electrode pads on the semiconductor chips 5 are electrically connected with the adherend 6 through bonding wires 7.

Subsequently, a sealing step of sealing the semiconductor chips 5 with a sealing resin 8 is performed to cure the sealing resin 8. In addition thereto, in the case of the above-mentioned temporary sticking/fixing, the adherend 6 and one of the semiconductor chips 5 are bonded to each other, and the semiconductor chips 5 and the spacer 9 are bonded to each other through the die-bonding films 3a and 21. In this way, a semiconductor package is obtained. The sealing step is preferably performed by a package sealing method wherein only the semiconductor chip 5 is sealed. The sealing is performed to protect the semiconductor chips 5 adhered onto the adhesive sheet(s). The method therefor is typically a method of using the sealing resin 8 and molding the resin 8 in a metal mold. At this time, it is general to use a metal mold composed of an upper metal mold part and a lower metal mold part and having plural cavities to seal simultaneously. The heating temperature at the time of the sealing preferably ranges, for example, from 170 to 180° C. After the sealing step, an after-curing step may be performed.

The spacer 9 is not particularly limited, and may be made of, for example, a silicon chip or polyimide film ant the like known in the prior art. The spacer may be a core member. The core member is not particularly limited, and may be a core member known in the prior art. Specific examples thereof include films (such as a polyimide film, a polyester film, a polyethylene terephthalate film, a polyethylene naphthalate film, a polycarbonate film and the like), resin substrates each reinforced with glass fiber or plastic nonwoven fiber, mirror silicon wafers, silicon substrates, and glass substrates.

Next, on a printed circuit board, the semiconductor package is surface-mounted. The surface mounting method includes, for example, a reflow soldering method of feeding a solder on a printed circuit board in advance and heat-melting the solder by warm wind thereby conducting soldering. The heating method is, for example, hot wind reflow or infrared ray reflow or the like. The workpiece may be wholly or partially heated. The heating temperature is preferably within a range from 230 to 280° C., and the heating time is preferably within a range from 1 to 360 seconds.

As shown in FIG. 6, without using the spacer 9, a plurality of semiconductor chips 5 may be layered through a die-bonding film to which some parts of bonding wires such as a gold wire are embedded, thereby attaining three-dimensional mounting (film-on-wire (FoW)). For the purpose of miniaturization of packages and simplification of steps, the mounting method of directly embedding a bonding wire 7 such as a gold wire using a die-bonding film has recently been used in place of a spacer method (see FIG. 5). In the case of using this mounting method, since the bonding wire needs to be embedded in the die attaching step, low tensile storage modulus is required in the B-stage, whereas, high tensile storage modulus is required in the high-temperature process such as a wire bonding step. Therefore, the tensile storage modulus of the die-bonding film needs to be changed by thermal setting or the like. Therefore, a thermal setting accelerator is used as the catalyst. However, when the thermosetting catalyst exhibits solubility in the epoxy resin, the storage stability at room temperature drastically deteriorates. However, according to the present invention, since a thermosetting catalyst having insolubility in the epoxy resin is used, it is possible to satisfy storage stability at room temperature. As a result, even in the case of the method of directly embedding the bonding wire using the die-bonding film, the thermosetting die-bonding film of the present invention can be suitably used.

FIG. 6 is a schematic sectional view showing an example in which two semiconductor chips 5 are three-dimensionally mounted through a die-bonding film 22. In the case of the three-dimensional mounting illustrated in FIG. 6, first, a die-bonding film 3a and a semiconductor chip 5 are successively layered on an adherend 6 to conduct die-bonding. Next, without conducting any thermal setting step of the die-bonding films 22, a wire bonding step is conducted. In this way, electrode pads on the semiconductor chip 5 are electrically connected to the adherend 6 using the bonding wires 7.

Subsequently, the die-bonding film 22 is layered on the semiconductor chip 5 while pressing. At this time, some parts of the bonding wires 7 are embedded in the die-bonding film 22. Subsequently, a new semiconductor chip 5 is layered on the die-bonding film 22, followed by die boding. Furthermore, without conducting a thermally setting step, a wire bonding step is conducted.

Thereafter, a sealing step of sealing the semiconductor chip 5 with a sealing resin 8 is conducted and the sealing resin 8 as well as the die-bonding films 3a and 22 are thermally set to adhere and fix the adherend 6 and the semiconductor chip 5 to each other and the semiconductor chips 5 to each other through the die-bonding film 22 by thermal setting. In this way, a semiconductor package is obtained. Conditions for the sealing step are the same as described above. In this aspect, a post-curing step may also be conducted.

Next, on a printed circuit board, the semiconductor package is surface-mounted. The surface mounting method includes, for example, a reflow soldering method of feeding a solder on a printed circuit board in advance and heat-melting the solder by warm wind thereby conducting soldering. The heating method is, for example, hot wind reflow or infrared ray reflow or the like. The workpiece may be wholly or partially heated. The heating temperature is preferably within a range from 240 to 265° C., and the heating time is preferably within a range from 1 to 20 seconds.

Below, preferred examples of the present invention are explained in detail. However, materials, addition amounts, and the like described in these examples are not intended to limit the scope of the present invention, and are only examples for explanation as long as there is no description of limitation in particular.

### Example 1

To 100 parts by weight of an acrylic acid ester-based polymer containing ethyl acrylate-methyl methacrylate as a main component (manufactured by Negami Chemical Industrial Co., Ltd., Paracron W-197CM), 87 parts by weight of a bisphenol A type epoxy resin 1 (manufactured by Japan Epoxy Resins Co., Ltd., Epikote 1004), 79 parts by weight of a bisphenol A type epoxy resin 2 (manufactured by Japan Epoxy Resins Co., Ltd., Epikote 827), 178 parts by weight of a phenol aralkyl resin (manufactured by Mitsui Chemicals, Inc., MILEX XLC-4L), 296 parts by weight of spherical silica (manufactured by Admatechs., SO-25R), and 0.2 parts by weight of tetraphenylphosphonium thiocyanate (trade name; TPP-SCN, manufactured by Hokko Chemical Industry Co., Ltd.) as a thermosetting catalyst were dissolved in methyl ethyl ketone to obtain an adhesive composition solution having a concentration of 23.6% by weight. The dissolution temperature at which each constituent material is dissolved in methyl ethyl ketone was 23° C., and the dissolution time required to dissolve the thermosetting catalyst in the solution without being crystallized was 20 minutes.

This adhesive composition solution was applied on a release-treated film (peel liner) composed of a 50 μm thick polyethylene terephthalate film subjected to a silicone release treatment and then dried at 130° C. for 2 minutes to produce a 40 μm thick die-bonding film A.

### Example 2

In the same manner as in Example 1, except that the addition amount of the thermosetting catalyst was changed to 1.0 part by weight in Example 2, a die-bonding film B according to the present Example was produced. In the production of the adhesive composition solution, the dissolution temperature at which each constituent material is dissolved in methyl ethyl ketone was 23° C., and the dissolution time required to dissolve the thermosetting catalyst in the solution without being crystallized was 20 minutes.

### Example 3

In the same manner as in Example 1, except that 0.2 parts by weight of 2,4-diamino-6-2[2′-methylimidazolyl-(1′)]-ethyl-s-triazinis ocyanuric acid adduct (trade name; 2MAOK-PW, manufactured by SHIKOKU CHEMICALS CORPORATION) was used as the thermosetting catalyst in Example 3, a die-bonding film C of the present Example was produced. In the production of the adhesive composition solution, the dissolution temperature at which each constituent material is dissolved in methyl ethyl ketone was 23° C., and the dissolution time required to dissolve the thermosetting catalyst in the solution without being crystallized was 20 minutes.

### Example 4

In the same manner as in Example 3, except that the addition amount of the thermosetting catalyst was changed to 1.0 part by weight in Example 4, a die-bonding film D according to the present Example was produced. In the production of the adhesive composition solution, the dissolution temperature at which each constituent material is dissolved in methyl ethyl ketone was 23° C., and the dissolution time required to dissolve the thermosetting catalyst in the solution without being crystallized was 20 minutes.

### Example 5

In the same manner as in Example 1, except that benzyltriphenylphosphonium tetraphenylborate (manufactured by Hokko Chemical Industry Co., Ltd., trade name; TPP-ZK) was used as the thermosetting catalyst and the addition amount thereof was changed to 1.0 part by weight in Example 5, a die-bonding film E according to the present Example was produced. In the production of the adhesive composition solution, the dissolution temperature at which each constituent material is dissolved in methyl ethyl ketone was 23° C., and the dissolution time required to dissolve the thermosetting catalyst in the solution without being crystallized was 20 minutes.

### Comparative Example 1

In the same manner as in Example 1, except that the addition amount of the thermosetting catalyst was changed to 0.1 part by weight in Comparative Example 1, a die-bonding film F according to the present Comparative Example was produced. In the production of the adhesive composition solution, the dissolution temperature at which each constituent material is dissolved in methyl ethyl ketone was 23° C., and the dissolution time required to dissolve the thermosetting catalyst in the solution without being crystallized was 20 minutes.

### Comparative Example 2

In the same manner as in Example 1, except that the addition amount of the thermosetting catalyst was changed to 1.5 part by weight in Comparative Example 2, a die-bonding film G according to the present Comparative Example was produced. In the production of the adhesive composition solution, the dissolution temperature at which each constituent material is dissolved in methyl ethyl ketone was 23° C., and the dissolution time required to dissolve the thermosetting catalyst in the solution without being crystallized was 20 minutes.

### Comparative Example 3

In the same manner as in Example 1, except that 2,4-diamino-6-[2′-methylimidazolyl-(1′)]-ethyl-s-triaziniso cyanuric acid adduct (trade name; 2MAOK-PW, manufactured by SHIKOKU CHEMICALS CORPORATION) was used as the thermosetting catalyst and the addition amount thereof was changed to 0.1 parts by weight in Comparative Example 3, a die-bonding film H according to Comparative Example 3 was produced. In the production of the adhesive composition solution, the dissolution temperature at which each constituent material is dissolved in methyl ethyl ketone was 23° C., and the dissolution time required to dissolve the thermosetting catalyst in the solution without being crystallized was 20 minutes.

### Comparative Example 4

In the same manner as in Example 1, except that 2,4-diamino-6-[2′-methylimidazolyl-(1′)]-ethyl-s-triaziniso cyanuric acid adduct (trade name; 2MAOK-PW, manufactured by SHIKOKU CHEMICALS CORPORATION) was used as the thermosetting catalyst and the addition amount thereof was changed to 1.5 parts by weight in Comparative Example 4, a die-bonding film I according to Comparative Example 4 was produced. In the production of the adhesive composition solution, the dissolution temperature at which each constituent material is dissolved in methyl ethyl ketone was 23° C., and the dissolution time required to dissolve the thermosetting catalyst in the solution without being crystallized was 20 minutes.

### Tensile Elongation at Break

Each of the die-bonding films A to I was cut into strip-shaped measuring specimens each measuring 40 mm in initial length and 10 mm in width. Using a Tensilon universal tester (RTE-1210, manufactured by A&D Company, Limited), a tensile fracture elongation at break at 25° C. was measured under the conditions of a tension rate of 10 mm/min and a distance between chucks of 30 mm. The measurement was conducted without storage of the die-bonding films A to I at room temperature and after storage at room temperature for 30 days (at 25° C., 55% RH).

High-Temperature Shearing Adhesive Strength After Thermal Setting

Each of the die-bonding films A to I was laminated to a semiconductor element at 40° C. and then mounted to a BGA substrate at 160° C. under 0.2 MPa. Subsequently, each of the die-bonding films A to I was thermally set under predetermined conditions, and then the shearing adhesive strength at 175° C. was measured. Heating treatment conditions under which each of the die-bonding films A to I is thermally set are as shown in Tables 1 and 2 below.

The shearing adhesive strength was measured as follows. That is, each test specimen was fixed to a temperature controllable hot plate and the shearing adhesive strength was measured by horizontally pressing a die-attached semiconductor element using a push pull gauge at a rate of 0.5 mm/second. As the measuring apparatus, a bump pull tester (manufactured by Dage Holdings Limited) was used.

Wafer Mounting Properties

Each of the die-bonding films A to I was stored at room temperature for 30 days (at 25° C., 55% RH). Thereafter, using a hot roll laminator, each die-bonding film was laminated on a wafer (having a diameter of 6 inch) under the lamination conditions of the temperature of 40° C., 0.1 m/minute and the pressure of 0.5 MPa. After lamination, with respect to the die-bonding films A to I, the presence or absence of cracks and chips was visually confirmed. As a result, a case where cracks and chip did not occur was rated as satisfactory wafer mounting properties (O), whereas, a case where cracks and chip occurred was rated poor wafer mounting properties (×).

Wire Bonding Properties

With respect to wire bonding properties, a case where the shearing adhesive strength at 175° C. of the die-bonding film after thermal setting was 0.2 MPa or more was rated Good “O”, whereas, a case where the shearing adhesive strength is less than 0.2 MPa was rated Poor “×”.

Regarding the wire bonding properties, in a case where a gold wire (diameter of 23 μm) for wire bonding was bonded by a thermosonic bonding method under the conditions of an ultrasonic output time of 10 ms, a bond load of 180.50 mN and a stage temperature of 175° C., when the shearing adhesive strength of the die-bonding film after thermal setting is 0.2 MPa or more, wire bonding success probability is 100% or more. Therefore, in the present Example, the shearing adhesive strength of 0.2 MPa at 175° C. of the die-bonding film after thermal setting was used as criteria for evaluation of wire bonding properties.

Results

As is apparent from the results in Tables 1 and 2 shown below, it was confirmed that the die-bonding films A to D, each containing a thermosetting catalyst in a non-crystalline state, of Examples 1 to 4 are excellent in storage stability of both elongation at break and wafer mounting properties after storage at room temperature for 30 days, and are also excellent in wire bonding properties.

In contrast, it was found that the die-bonding films F and H, each containing 0.1 parts by weight of a thermosetting catalyst in a non-crystalline state, of Comparative Examples 1 and 3 exhibit extremely low shearing adhesive strength after thermal setting, and wire bonding properties deteriorate. Thus, it was confirmed that the die-bonding films F, H are not sufficiently thermally set by a heating treatment at 120° C. for 1 hour. It was also confirmed that, in the bonding films G and I, each containing 1.5 parts by weight of the thermosetting catalyst, of Comparative Examples 2 and 4, storage stability at room temperature of elongation at break and wafer mounting properties deteriorate.

TABLE 1

| | Example 1 | Example 2 | Example 3 | Example 4 | Example 5 |
|---|---|---|---|---|---|
| | Die-bonding | Die-bonding | Die-bonding | Die-bonding | Die-bonding |
| | film A | film B | film C | film D | film E |
| Thermosetting | TPP | TPP | 2MAOK-PW | 2MAOK-PW | TPP-ZK |
| catalyst | | | | | |
| Amount of | 0.2 | 1.0 | 0.2 | 1.0 | 1.0 |
| thermosetting | | | | | |
| catalyst to be | | | | | |
| blended (parts by | | | | | |
| weight) | | | | | |
| Elongation at | 510% | 480% | 490% | 500% | 520% |
| break (storing at | | | | | |
| room temperature | | | | | |
| for 0 day) | | | | | |
| Elongation at | 335% | 220% | 330% | 250% | 335% |
| break (after | | | | | |
| storage at room | | | | | |
| temperature for | | | | | |
| 30 days) | | | | | |
| Mounting | ◯ | ◯ | ◯ | ◯ | ◯ |
| properties after | | | | | |
| storage at room | | | | | |
| temperature for | | | | | |
| 30 days | | | | | |
| Thermosetting | at 120° C. for | at 120° C. for | at 120° C. for | at 120° C. for | at 120° C. for |
| conditions | 1 hour | 1 hour | 1 hour | 1 hour | 1 hour |
| High-temperature | 1.0 | 3.6 | 0.8 | 2.7 | 0 |
| shearing | | | | | |
| adhesive | | | | | |
| strength after | | | | | |
| thermal setting | | | | | |
| (MPa) | | | | | |
| Wire bonding | ◯ | ◯ | ◯ | ◯ | X |
| properties after | | | | | |
| thermal setting | | | | | |

TABLE 2

| | Comparative | Comparative | Comparative | Comparative |
|---|---|---|---|---|
| | Example 1 | Example 2 | Example 3 | Example 4 |
| | Die-bonding | Die-bonding | Die-bonding | Die-bonding |
| | film F | film G | film H | film I |
| Thermosetting catalyst | TPP | TPP | 2MAOK-PW | 2MAOK-PW |
| Amount of thermosetting | 0.1 | 1.5 | 0.1 | 1.5 |
| catalyst to be blended (parts by | | | | |
| weight) | | | | |
| Elongation at break (storing at | 510% | 470% | 530% | 520% |
| room temperature for 0 day) | | | | |
| Elongation at break (after | 320% | 102% | 320% | 130% |
| storage at room temperature for | | | | |
| 30 days) | | | | |
| Mounting properties after | ∘ | x | ∘ | x |
| storage at room temperature for | | | | |
| 30 days | | | | |
| Thermosetting conditions | at 120° C. for | at 120° C. for | at 120° C. for | at 120° C. for |
| | 1 hour | 1 hour | 1 hour | 1 hour |
| High-temperature shearing | 0.05 | 5.2 | 0 | 3.2 |
| adhesive strength after | | | | |
| thermal setting (MPa) | | | | |
| Wire bonding properties after | x | ∘ | x | ∘ |
| thermal setting | | | | |

1. A thermosetting die-bonding film used to produce a semiconductor device, comprising a thermosetting catalyst in a non-crystalline state in an amount within a range from 0.2 to 1 part by weight based on 100 parts by weight of an organic component in the film.

2. The thermosetting die-bonding film according to claim 1, wherein the film contains a phenol resin, and the thermosetting catalyst has an imidazole skeleton and also exhibits solubility in the phenol resin.

3. The thermosetting die-bonding film according to claim 1, wherein the thermosetting catalyst is a salt having a triphenylphosphine structure, a salt having a triphenylborane structure, or has an amino group.

4. The thermosetting die-bonding film according to claim 1, wherein the thermosetting catalyst is a photo-acid-generating agent.

5. The thermosetting die-bonding film according to claim 1, which has a tensile fracture elongation at break of 200% or more after storage at room temperature for 30 days or more in at least one direction of a longitudinal direction and a width direction.

6. The thermosetting die-bonding film according to claim 1, which has a tensile storage modulus of 10 MPa or more after thermal setting at 260° C.

7. The thermosetting die-bonding film according to claim 1, which has a surface energy of 40 mJ/m² or less on the laminating surface after thermal setting.

8. The thermosetting die-bonding film according to claim 1, which has a moisture absorptivity of 1% by weight or less when the thermosetting die-bonding film is allowed to stand under the atmosphere of 85° C. and 85% RH for 168 hours after thermal setting.

9. The thermosetting die-bonding film according to claim 1, which has a weight loss of 1% by weight or less after heating at 250° C. for 1 hour after thermal setting.

10. A dicing die-bonding film comprising dicing film and the thermosetting die-bonding film according to claim 1 layered on the dicing film, wherein the dicing film has a structure including a base material and a pressure-sensitive adhesive layer layered on the base material, and the thermosetting die-bonding film is layered on the adhesive layer.

11. A method for producing a semiconductor device using the dicing die-bonding film according to claim 10, comprising:
a mounting step of laminating the dicing die-bonding film on a back surface of a semiconductor wafer using the thermosetting die-bonding film as a laminating surface;
a dicing step of dicing the semiconductor wafer together with the thermosetting die-bonding film to form a chip-shaped semiconductor element;
a pickup step of picking up the semiconductor element from the dicing die-bonding film together with the thermosetting die-bonding film;
a die-bonding step of die-bonding the semiconductor element on an adherend through the thermosetting die-bonding film;
a thermal setting step of thermally setting the thermosetting die-bonding film by heating at a heating temperature within a range from 80 to 200° C. and a heating time within a range from 0.1 to 24 hours; and
a wire bonding step of wire bonding to the semiconductor element.

12. The thermosetting die-bonding film according to claim 1, wherein the thermosetting catalyst is uniformly mixed in the thermosetting die-bonding film.

13. The thermosetting die-bonding film according to claim 1, wherein the thermosetting die-bonding film comprises a thermosetting resin and a thermoplastic resin.

14. The thermosetting die-bonding film according to claim 1, wherein, upon thermosetting the film under temperature from 80 to 200° C. for 0.1 to 24 hours, the die-bonding film has a shearing adhesive strength to an adherend of 0.2 MPa to 10 MPa.
